(19) United States
(12) Patent Application Publication
(10) Pub. No.: US 2014/0284537 A1
(43) Pub. Date: Sep. 25, 2014

(54) MEMORY ELEMENT

(71) Applicant: KABUSHIKI KAISHA TOSHIBA, Tokyo (JP)

(72) Inventor: Junichi WADA, Mie-ken (JP)

(21) Appl. No.: 14/022,482

(22) Filed: Sep. 10, 2013

Related U.S. Application Data
(60) Provisional application No. 61/804,404, filed on Mar. 22, 2013.

(51) Int. Cl. H01L 45/00

(52) U.S. Cl. CPC H01L 45/145
USPC 257/2

(57) ABSTRACT

According one embodiment, a memory element includes: a first electrode layer; a second electrode layer including a metal element; and a memory layer provided between the first electrode layer and the second electrode layer, the memory layer including an oxide layer, and a platinum group metal being dispersed in at least part of the oxide layer, an absolute value of a standard Gibbs free energy of formation of an oxide of an element included in the oxide layer being larger than an absolute value of a standard Gibbs free energy of formation when the metal element changes to an oxide.

### CROSS-REFERENCE TO RELATED APPLICATION

This application is based upon and claims the benefit of priority from U.S. Provisional Patent Application 61/804404, filed on Mar. 22, 2013; the entire contents of which are incorporated herein by reference.

### FIELD

Embodiments described herein relate generally to a memory element.

### BACKGROUND

There is a resistance change memory as a memory device. The resistance change memory is less influenced by shrinking and is capable of achieving a large capacity, and is therefore drawing attention as a next-generation nonvolatile memory. The resistance change memory is composed of resistance change elements (cells), and utilizes the characteristic that the resistance of a resistance change film is changed by applying a voltage to the film via upper and lower electrodes to pass a current through the film. Examples of the resistance change film include a large number of oxide films such as transition metal oxide films. In the case where, for example, a transition metal oxide film is used as the resistance change film, the initial state is high resistive, and the forming operation for making the film low resistive in the beginning may be performed. However, the forming operation may take a long time.

### BRIEF DESCRIPTION OF THE DRAWINGS

FIG. 1A is an example of a schematic cross-sectional view of a memory device using a memory element according to a first embodiment, FIG. 1B is an example of a circuit diagram of a memory cell array including the memory element according to the first embodiment, and FIG. 1C is an example of the memory element according to the first embodiment;

FIG. 2A to FIG. 2C are examples of schematic cross-sectional views showing operations of the memory element according to the first embodiment;

FIG. 3A is an example of a schematic cross-sectional view of a memory element of a first example according to a second embodiment, and FIG. 3B is an example of a schematic cross-sectional view of a memory element of a second example according to the second embodiment; and

FIG. 4A is an example of a schematic cross-sectional view of a memory element of a first example according to a third embodiment, and FIG. 4B is an example of a schematic cross-sectional view of a memory element of a second example according to the third embodiment.

### DETAILED DESCRIPTION

In general, according one embodiment, a memory element includes: a first electrode layer; a second electrode layer including a metal element; and a memory layer provided between the first electrode layer and the second electrode layer, the memory layer including an oxide layer, and a platinum group metal being dispersed in at least part of the oxide layer, an absolute value of a standard Gibbs free energy of formation of an oxide of an element included in the oxide layer being larger than an absolute value of a standard Gibbs free energy of formation when the metal element changes to an oxide.

Hereinbelow, embodiments are described with reference to the drawings. In the following description, identical components are marked with the same reference numerals, and a description of components once described is omitted as appropriate.

### First Embodiment

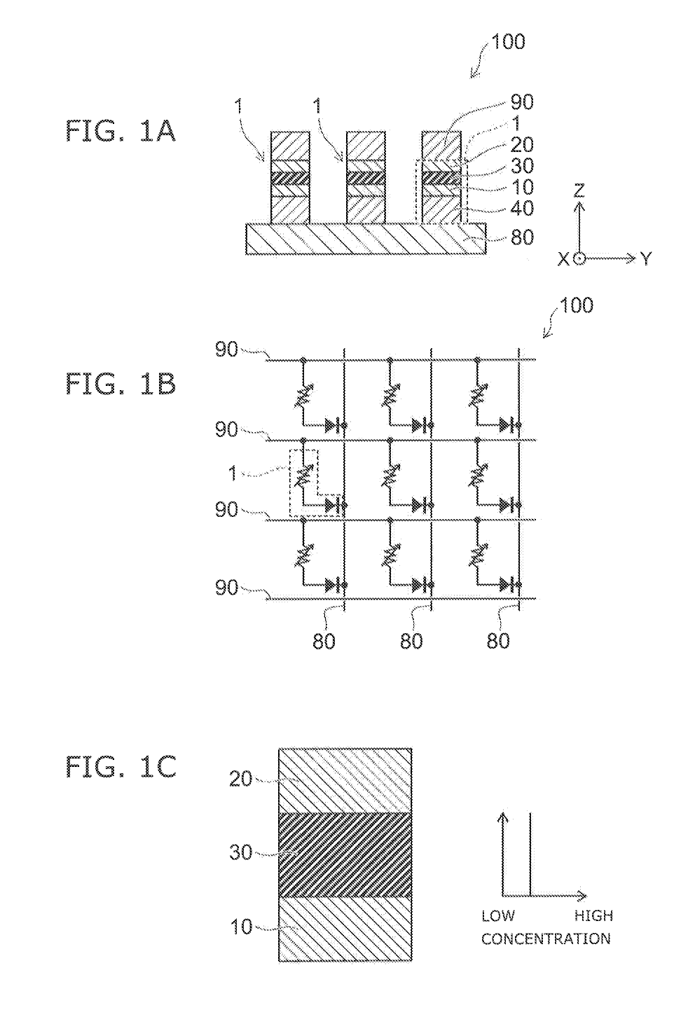

FIG. 1A is an example of a schematic cross-sectional view of a memory device using a memory element according to a first embodiment, and FIG. 1B is an example of a circuit diagram of a memory cell array including the memory element according to the first embodiment. FIG. 1C is an example of the memory element according to the first embodiment.

As shown in FIG. 1A and FIG. 1B, a memory cell array 100 is a cross-point memory cell array. The memory cell array 100 includes bit lines 80 and word lines 90 crossing the bit lines 80. Each of the bit lines 80 and each of the word lines 90 are substantially orthogonal. A memory element 1 is provided in a position where each of the bit lines 80 and each of the word lines 90 cross each other.

The memory element 1 shown in FIG. 1A is a resistance change memory element. The memory element 1 includes an electrode layer 10 (a first electrode layer), an electrode layer 20 (a second electrode layer), and a memory layer 30. The memory layer 30 may be referred to a resistance change layer 30. The electrode layer 10 and the electrode layer 20 contain a metal element. The memory layer 30 is provided between the electrode layer 10 and the electrode layer 20. The memory layer 30 includes an oxide layer in which a platinum group metal is dispersed in at least part of the oxide layer. FIG. 1C shows, as an example, a state where a platinum group metal is uniformly dispersed in the oxide layer. The oxide layer is in contact with the electrode layer 20. An insulating layer (not shown) is provided around each of the memory elements 1. Thereby, the insulation between adjacent ones of the memory elements 1 is maintained.

The absolute value of the standard Gibbs free energy of formation of the oxide contained in the oxide layer is larger than the absolute value of the standard Gibbs free energy of formation when the metal element contained in the electrode layer 20 changes to an oxide. The standard Gibbs free energy of formation of the oxide contained in the oxide layer is expressed as ΔGₐ (kJ/mol, 298.15 K), for example. The standard Gibbs free energy of formation when the metal element contained in the electrode layer 20 changes to an oxide is expressed as ΔG_{b}. In this case, the absolute value of ΔGₐ is larger than the absolute value of ΔG_{b}.

The memory element 1 further includes a selector 40. FIG. 1A shows a state where the selector 40 is provided on the lower side of the electrode layer 10. The selector 40 may be provided between the electrode layer 10 and the memory layer 30. Also a structure in which the stacked structure shown in FIG. 1A is turned upside down is included in the embodiment. The selector refers to a diode through which a current flows in one direction and a current does not flow in the opposite direction thereof, or an element through which a current does not flow at or below a certain positive or negative threshold voltage and a current flows forward or backward upon exceeding the threshold voltage.

An electric potential of a negative polarity (a first polarity) can be applied to the electrode layer 10 via the bit line 80, and an electric potential of a positive polarity (a second polarity) can be applied to the electrode layer 20 via the word line 90. Furthermore, an electric potential of a positive polarity can be applied to the electrode layer 10 via the bit line 80, and an electric potential of a negative polarity can be applied to the electrode layer 20 via the word line 90. That is, the memory cell array 100 includes a bipolar memory element 1.

The platinum group metal is at least one selected from the group consisting of platinum (Pt), palladium (Pd), iridium (Ir), rhodium (Rh), osmium (Os), and ruthenium (Ru). The oxide layer in which a platinum group metal is introduced is formed by, for example, PVD (physical vapor deposition), CVD (chemical vapor deposition), ALD (atomic layer deposition), or the like.

The electrode layer 10 contains, for example, at least one selected from the group consisting of tungsten (W), aluminum (Al), titanium nitride (TiN), and the like. The electrode layer 20 contains, for example, at least one selected from the group consisting of platinum (Pt), ruthenium (Ru), cobalt (Co), tungsten (W), titanium (Ti), titanium nitride (TiN), and the like.

The oxide layer included in the memory layer 30 contains at least one selected from the group consisting of hafnium oxide (HfOₓ), zirconium oxide (ZrOₓ), tantalum oxide (TaOₓ), niobium oxide (NbOₓ), titanium oxide (TiOₓ), and the like. The coefficients of the elements of the composition formulae of these oxides are deviated from the stoichiometric coefficients. The selector 40 is, for example, a field effect transistor, a tunnel diode, or the like,

Operations of the memory element 1 are described.

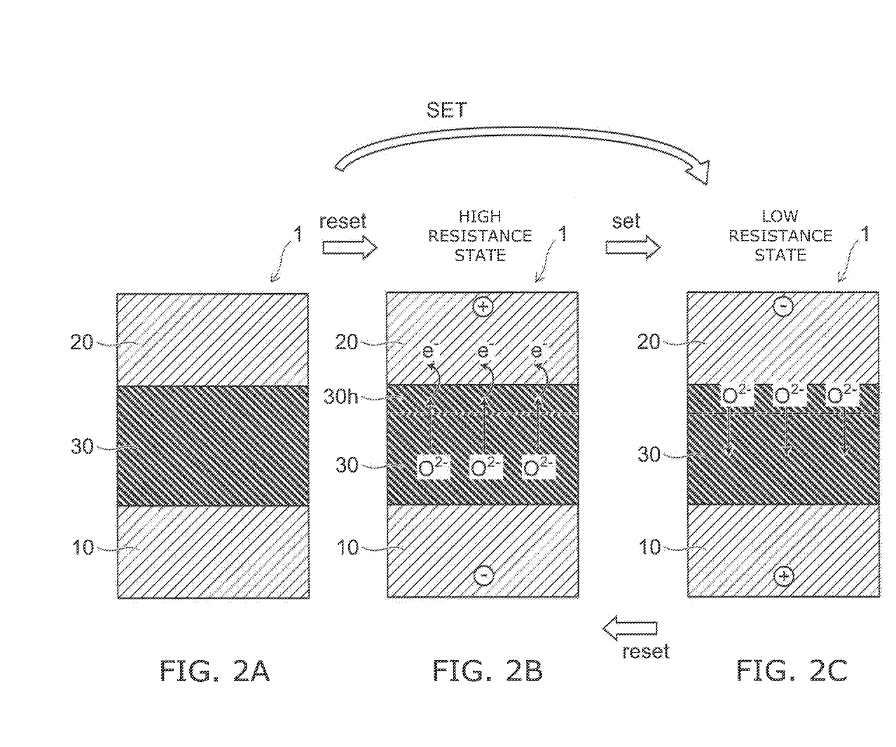

FIG. 2A to FIG. 2C are examples of schematic cross-sectional views showing operations of the memory element according to the first embodiment.

FIG. 2A shows a state (initial state) before the memory element 1 performs the set operation and the reset operation. In the state shown in FIG. 2A, no voltage is applied to each of the electrode layer 10 and the electrode layer 20. It is assumed that the coefficients of the elements of the composition formula of the oxide in the memory layer 30 are deviated from the stoichiometric composition. The resistivity of the oxide in the memory layer 30 is lower than the resistivity of the oxide of the stoichiometric composition. That is, the oxide in the memory layer 30 is in a state of oxygen deficiency. Therefore, a small current can flow through the memory layer 30. In the state shown in FIG. 2A, for example, the oxygen concentration (mol/cm³) in the memory layer 30 is substantially uniform in the direction from the electrode layer 10 toward the electrode layer 20 as shown in FIG. 1C.

It is possible to switch to a low resistance state by the set operation from the initial state, or switch to a high resistance state by the reset operation.

FIG. 2B is an example of the potential state showing the reset operation. FIG. 2B shows a state where an electric potential of a negative polarity is applied to the electrode layer 10 and an electric potential of a positive polarity is applied to the electrode layer 20. That is, in FIG. 2B, the electrode layer 10 is a negative electrode, and the electrode layer 20 is an anode. When the electrode layer 10 forms a negative electrode and the electrode layer 20 forms a positive electrode, an electric field is applied also to the memory layer 30.

By an electric field being applied to the memory layer 30, the oxygen in the memory layer 30 is ionized. The oxygen ions are minus ions, and therefore the oxygen ions move through the memory layer 30 in an oxygen deficient state and are diffused to the side of the electrode layer 20, which is an anode. The oxygen ions can fill the oxygen defect in an oxygen deficient state near the electrode layer 20. The electrons possessed by the oxygen ions flow to the electrode layer 20.

Thereby, a high resistance region 30h with a high resistance is produced near the interface between the electrode layer 20 and the memory layer 30, Here, since the absolute value of ΔG (free energy of formation of oxide of constituent element in the memory layer 30) is larger than the absolute value of ΔG (free energy of formation of oxide of the electrode layer 20), the oxygen ions in the memory layer 30 fill the oxygen deficient portion of the resistance change layer near the interface with the electrode layer 20, and form the high resistance region 30h. The oxide in the high resistance region 30h is in a state of the stoichiometric composition or a state near the stoichiometric composition. That is, assuming that the state of the memory layer 30 shown in FIG. 2A is the low resistance state, the state of the memory layer 30 shown in FIG. 2B is a state where part of the memory layer 30 has been turned to the high resistance state. Changing the state of the memory layer 30 from the low resistance state to the high resistance state is defined as the reset operation. The state of the memory element 1 in the high resistance state is put as, for example, information “0”.

FIG. 2C is an example of the potential state showing the set operation. FIG. 2C shows a state where an electric potential of a positive polarity is applied to the electrode layer 10 and an electric potential of a negative polarity is applied to the electrode layer 20. In this case, in the memory layer 30, the electric field is applied preferentially to the high resistance region 30h. This is because the resistivity of the high resistance region 30h is relatively high in the memory layer 30. Therefore, oxygen ions are generated preferentially in the high resistance region 30h.

The oxygen ions are diffused to the side of the electrode layer 10, which is an anode. Consequently, the oxygen concentration of the high resistance region 30h is decreased. The electrons possessed by the oxygen ions flow to the electrode layer 10. That is, the high resistance region 30h disappears, and the memory layer 30 returns to the low resistance state. Changing the state of the memory layer 30 from the high resistance state to the low resistance state is defined as the set operation. The state of the memory element in the low resistance state is taken as, for example, information “1”.

Thus, in the memory element 1, the polarity of the voltage applied to the memory layer 30 is changed to produce or eliminate the high resistance region 30h formed near the electrode layer 20; thereby, information can be written or erased.

In the memory element 1 according to the first embodiment, a platinum group element is introduced in the oxide layer. The platinum group element is substituted with part of the metal element of the oxide layer. The platinum group element has the property of being less likely to form an oxide, and therefore a reaction is less likely to occur between an oxygen ion and the platinum group element. Thus, oxygen ions and the metal in the oxide layer near the anode react with good efficiency, and the high resistance region 30h is stably produced near the anode.

The platinum group element has a catalytic action. Therefore, the ionization of the oxygen in the oxide layer is promoted. That is, the oxygen is ionized by the application of an electric field and the catalytic action of the platinum group element. Consequently, in the memory element 1 of the embodiment, the memory layer 30 can be reset or set by a relatively low voltage as compared to a memory layer in which no platinum group element is introduced. Thereby, the power consumption of the memory element is reduced.

When the resetting and setting of the memory layer 30 are possible at a low voltage, the electrical load on the memory layer 30 is reduced. Therefore, the durability of the memory element is improved.

The memory element 1 is not what is called a filament-type memory element, In the memory element 1, the oxygen concentration in the oxide layer in contact with the entire region of the electrode layer 20 changes. Thus, in the memory element 1, the forming operation essential to the filament-type memory element is not needed.

For example, in the case where a resistance change layer formed of a transition metal oxide film is used, an operation called the forming operation takes a long time. The forming operation turns a high resistance filament to a low resistance state. A large current may flow at the time of forming or setting, and the resistance change film may be broken. In addition, due to the forming, the resistance at the time of setting will become too low and a large reset current will flow; thus, a drive circuit element and a protection circuit element may be broken. In addition, the forming may cause phenomena in which the voltage and the current value in setting and resetting vary, the difference between the set voltage and the reset voltage is reduced, and the voltage threshold of the lead cannot be established.

When resistance changes occur due to the oxidation of part of the filament formed in the forming and the re-breaking of the oxide layer formed, there is a trade-off between increasing the number of times of data retention and increasing the data retention time, and thereby reliability may not be ensured. In the first embodiment, since the forming operation is not needed, these faults are less likely to occur.

In the first embodiment, the production and elimination of the high resistance region 30h occur stably. Therefore, the resistance difference between the low resistance state that is the ON state and the high resistance state that is the OFF state (R_{off}/Rₒₙ ratio) is large, and the possibility of false reading is reduced. Furthermore, since the resistance difference (R_{off}/Rₒₙ ratio) is high, separation into resistance states becomes possible. Therefore, a multiple-valued operation is enabled, Thereby, the integration degree of the memory device is further increased.

In the first embodiment, the memory layer 30 is not made a multiple-layer structure, and a platinum group metal is introduced into the memory layer 30. Therefore, the manufacturing process is simplified, and an increase in manufacturing costs is not caused.

### Second Embodiment

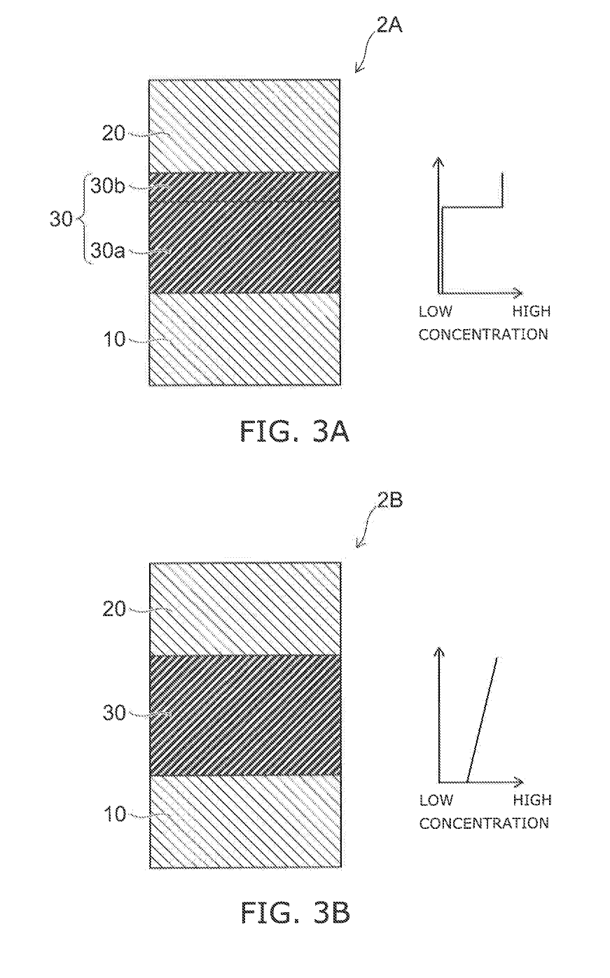

FIG. 3A is an example of a schematic cross-sectional view of a memory element of a first example according to a second embodiment, and FIG. 3B is an example of a schematic cross-sectional view of a memory element of a second example according to the second embodiment.

The concentration distribution of the platinum group metal in the memory layer 30 is shown on the right side of the drawings of memory elements of FIG. 3A and FIG. 3B.

In memory elements 2A and 2B according to the second embodiment, in the memory layer 30, the concentration of the platinum group metal in the oxide layer is higher on the electrode layer 20 side than on the electrode layer 10 side.

For example, in the memory element 2A shown in FIG. 3A, the oxide layer included in the memory layer 30 includes a first region 30a and a second region 30b. The first region 30a is provided on the electrode layer 10 side, and the second region 30b is provided on the electrode layer 20 side. The concentration of the platinum group metal of the second region 30b is higher than the concentration of the platinum group metal of the first region 30a. Here, the concentration of the oxide layer changes greatly at the boundary between the first region 30a and the second region 30b. Also an example in which no platinum group metal is introduced in the first region 30a is included in the second embodiment.

In the memory element 2A, the concentration of the platinum group metal near the interface between the electrode layer 20 and the memory layer 30 is high. Therefore, the oxygen deficiency of the oxide layer near the interface between the electrode layer 20 and the memory layer 30 can be compensated for by oxygen ions more easily. That is, the high resistance region 30h is more stably produced and eliminated near the interface between the electrode layer 20 and the memory layer 30. Thereby, the durability of the memory element is further improved.

The structure in which the concentration of the platinum group metal in the oxide layer is higher on the electrode layer 20 side than on the electrode layer 10 side is not limited to the structure shown in the memory element 2A. For example, like the memory element 2B shown in FIG. 3B, also a structure in which the concentration of the platinum group metal in the oxide layer increases gradually from the electrode layer 10 side toward the electrode layer 20 side is possible.

### Third Embodiment

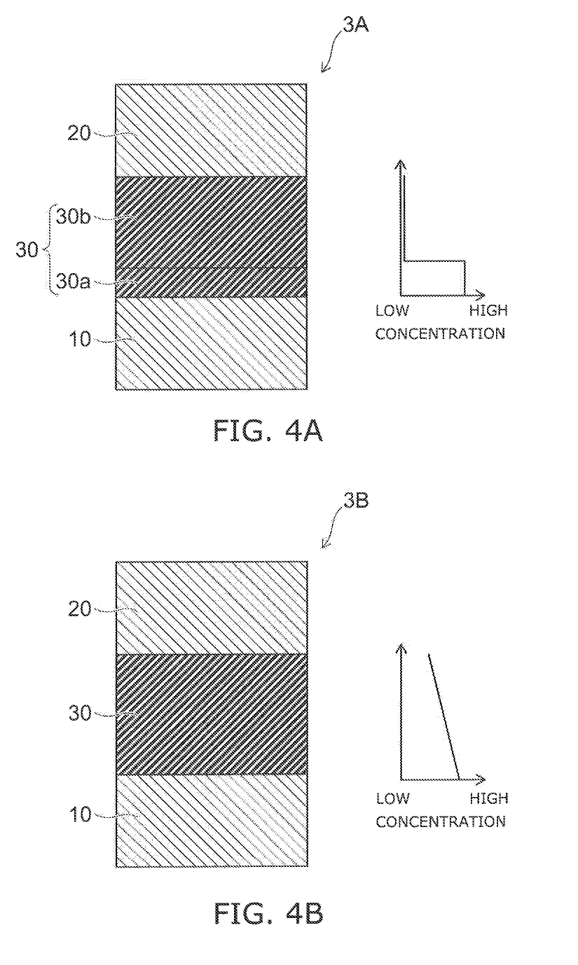

FIG. 4A is an example of a schematic cross-sectional view of a memory element of a first example according to a third embodiment, and FIG. 4B is an example of a schematic cross-sectional view of a memory element of a second example according to the third embodiment.

The concentration distribution of the platinum group metal in the memory layer 30 is shown on the right side of the drawings of memory elements of FIG. 4A and FIG. 4B,

The structure of the memory layer 30 is not limited to the structure of the second embodiment described above, and also a structure in which the structure of the second embodiment is turned upside down is possible. In this case, the material of the electrode layer 10 and the material of the electrode layer 20 may be exchanged.

For example, in memory elements 3A and 3B according to the third embodiment, in the memory layer 30, the concentration of the platinum group metal in the oxide layer is lower on the electrode layer 20 side than on the electrode layer 10 side.

For example, in the memory element 3A shown in FIG. 4A, the oxide layer included in the memory layer 30 includes a first region 30a and a second region 30b. The first region 30a is provided on the electrode layer 10 side, and the second region 30b is provided on the electrode layer 20 side. The concentration of the platinum group metal of the second region 30b is lower than the concentration of the platinum group metal of the first region 30a. Here, the concentration of the oxide layer changes greatly at the boundary between the first region 30a and the second region 30b. Also an example in which no platinum group metal is introduced in the second region 30b is included in the third embodiment.

In the memory element 3A, the concentration of the platinum group metal near the interface between the electrode layer 10 and the memory layer 30 is high. Therefore, the oxygen deficiency of the oxide layer near the interface between the electrode layer 10 and the memory layer 30 can be compensated for by oxygen ions more easily. That is, the high resistance region 30h is more stably produced and eliminated near the interface between the electrode layer 10 and the memory layer 30. Thereby, the durability of the memory element is further improved.

The structure in which the concentration of the platinum group metal in the oxide layer is lower on the electrode layer 20 side than on the electrode layer 10 side is not limited to the structure shown in the memory element 3A. For example, like the memory element 3B shown in FIG. 4B, also a structure in which the concentration of the platinum group metal in the oxide layer decreases gradually from the electrode layer 10 side toward the electrode layer 20 side is possible.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

The term “on” in “a portion A is provided on a portion B” refers to the case where the portion A is provided on the portion B such that the portion A is in contact with the portion B and the case where the portion A is provided above the portion B such that the portion A is not in contact with the portion B.

Furthermore, the components included in the above embodiments can be combined as long as technically feasible. Such combinations are also encompassed within the scope of the embodiments as long as they include the features of the embodiments, In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A memory element comprising:
a first electrode layer;
a second electrode layer including a metal element; and
a memory layer provided between the first electrode layer and the second electrode layer, the memory layer including an oxide layer, and a platinum group metal being dispersed in at least part of the oxide layer,
an absolute value of a standard Gibbs free energy of formation of an oxide of an element included in the oxide layer being larger than an absolute value of a standard Gibbs free energy of formation when the metal element changes to an oxide.

2. The memory element according to claim 1, wherein the platinum group metal is at least one selected from the group consisting of platinum (Pt), palladium (Pd), iridium (Ir), rhodium (Rh), osmium (Os), and ruthenium (Ru).

3. The memory element according to claim 1, wherein the platinum group metal is uniformly dispersed in the oxide layer.

4. The memory element according to claim 1, wherein a concentration of the platinum group metal in the oxide layer is higher on the second electrode layer side than on the first electrode layer side.

5. The memory element according to claim 1, wherein
the oxide layer includes a first region and a second region,
the first region is provided on the first electrode layer side and the second region is provided on the second electrode layer side, and
a concentration of the platinum group metal of the second region is higher than a concentration of the platinum group metal of the first region.

6. The memory element according to claim 1, wherein a concentration of the platinum group metal in the oxide layer increases from the first electrode layer side toward the second electrode layer side.

7. The memory element according to claim 1, wherein a concentration of the platinum group metal in the oxide layer is lower on the second electrode layer side than on the first electrode layer side.

8. The memory element according to claim 1, wherein
the oxide layer includes a first region and a second region,
the first region is provided on the first electrode layer side and the second region is provided on the second electrode layer side, and
a concentration of the platinum group metal of the second region is lower than a concentration of the platinum group metal of the first region.

9. The memory element according to claim 1, wherein a concentration of the platinum group metal in the oxide layer decreases from the first electrode layer side toward the second electrode layer side.

10. The memory element according to claim 1, wherein
the oxide layer is in contact with the second electrode layer and
an oxygen concentration in the oxide layer in contact with an entire region of the second electrode layer is variable.

11. The memory element according to claim 1, wherein an electric potential of a first polarity can be applied to the first electrode layer and an electric potential of a second polarity can be applied to the second electrode layer, or
an electric potential of a second polarity can be applied to the first electrode layer and an electric potential of a first polarity can be applied to the second electrode layer.
